(19) United States
(12) Patent Application Publication
(10) Pub. No.: US 2008/0239633 A1
(43) Pub. Date: Oct. 2, 2008

(54) HOUSING MECHANISM WITH HOOK FOR PORTABLE ELECTRONIC DEVICE

(75) Inventors: ZHENG SHI, Shenzhen (CN); DIAN-HONG YE, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: SHENZHEN FUTAIHONG PRECISION INDUSTRY CO., LTD., ShenZhen City (CN); SUTECH TRADING LIMITED, Tortola (VG)

(21) Appl. No.: 11/845,733

(22) Filed: Aug. 27, 2007

(30) Foreign Application Priority Data
Mar. 30, 2007 (CN) 200710073754.X

(51) Int. Cl. H05K 5/02

(52) U.S. Cl. 361/679

(57) ABSTRACT

A housing mechanism (100) includes a body (10). A hook (14) is formed on the body. The body has a receiving portion (12) defined therein and correspondingly has a first wall (1222) and a second wall (1224, 1242, 1244). The hook has a hook body (142) and at least one arm (144). The hook body extends from the first wall, towards the second wall, and above the receiving portion. The at least one arm extends from the hook body and above the receiving portion. There is a first space between the hook body and the second wall. There is a second space between the at least one arm and the second wall. The receiving portion and the hook together are able to receive a line to allow, e.g., decorative items to be hung upon the body.

### BACKGROUND OF THE INVENTION

1. Field of the Invention

The present invention generally relates to housing mechanisms for portable electronic devices and, particularly, to a housing mechanism with a hook (i.e., a hanging element) configured (i.e., structured and arranged) for hanging an accessory on the housing mechanism of a portable electronic device.

2. Discussion of the Related Art

With the development of recent technology of information processing, portable electronic devices, such as digital cameras, MP3 players, video cameras, mobile phone, and personal digital assistants (PDAs), are widely used. Often, an accessory is desirably hung on a housing mechanism of the portable electronic device for aesthetic purposes.

An accessory is mounted on a given housing mechanism with, e.g., a line or chain. A typical housing mechanism defines an arched through hole in a corner and forms a beam above the hole. In assembly, one portion of the line travels through the hole and surrounds the beam, thereby mounting the accessory on the housing mechanism. However, the hole is usually small, which makes it hard for the line to travel therethrough.

Therefore, a new housing mechanism with a hook is desired, in order to overcome the above-described shortcoming.

### SUMMARY

In one embodiment thereof, a present housing mechanism includes a body. A hook is formed on the body. The body has a receiving portion defined therein and has a first wall and a second wall corresponding to the receiving portion. The hook contains a hook body with at least one arm. The hook body extends from the first wall towards the second wall and above the receiving portion. The at least one arm extends from the hook body and above the receiving portion. There is a first space between the hook body and the second wall. There is a second space between the at least one arm and the second wall.

Other advantages and novel features of the embodiments will become more apparent from the following detailed description thereof when taken in conjunction with the accompanying drawings.

### BRIEF DESCRIPTION OF THE DRAWINGS

Many aspects of the present housing mechanism can be better understood with reference to the following drawings. The components in the drawings are not necessarily to scale, the emphasis instead being placed upon clearly illustrating the principles of the present housing mechanism. Moreover, in the drawings, like reference numerals designate corresponding parts throughout the several views.

FIG. 1 is an isometric, side view of a housing mechanism with a line attached thereto, in accordance with a first present embodiment;

FIG. 2 is a cut-away view of the housing mechanism, taken along line II-II in FIG. 1;

FIGS. 3 (a)-(d) are enlarged views in area III in FIG. 1, showing a process for mounting the line to the present housing mechanism;

FIG. 4 is an isometric, side view of a present housing mechanism, in accordance with a second embodiment; and

FIG. 5 is an isometric, side view of a present housing mechanism, in accordance with a third embodiment.

### DETAILED DESCRIPTION OF THE EMBODIMENT

The present housing mechanism is suitable for portable electronic devices, such as digital cameras, MP3 players, video cameras, mobile phones, PDAs, and the like, but could find other applications in which a similar housing mechanism is employed.

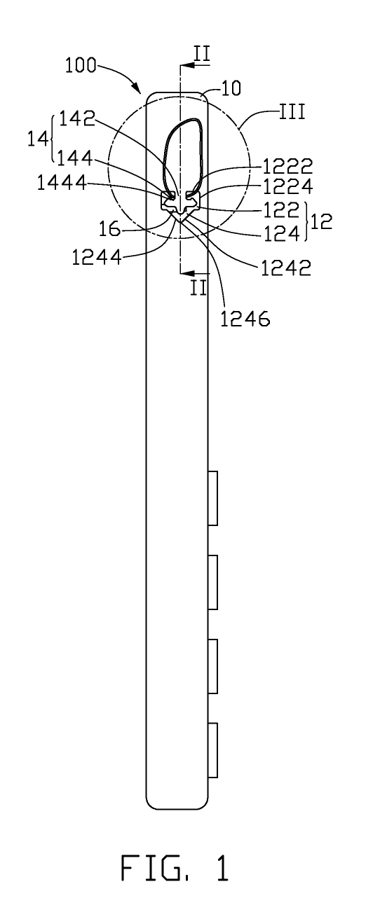

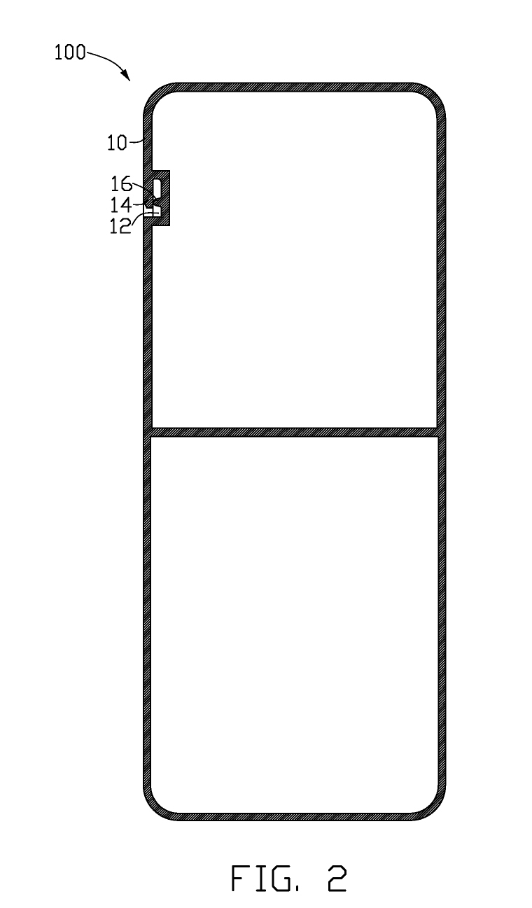

Referring to the drawings in detail, FIG. 1 shows a housing mechanism 100 used with a line 18, according to a first present embodiment. Also referring to FIG. 2, the housing mechanism 100 includes a body 10. A hook 14 is formed on the body 10. The line 18 could be used to facilitate the attachment of, e.g., a decorative item to the housing mechanism 100. Inversely, the line 18 could allow the housing mechanism 100 to be attached to another item, such as a backpack, purse, etc., for ease of carrying, or to be, e.g., hung on a hook for storage purposes.

The body 10 is substantially a rectangular parallelepiped in shape. A sidewall of the body 10 defines a receiving portion 12 therein. The receiving portion 12 has a first cavity 122 and a second cavity 124. The first cavity 122 communicates with the second cavity 124. The first cavity 122 is substantially quadrate, and, correspondingly, the body 10 has a top wall 1222 and two sidewalls 1224 that bound the first cavity 122. The second cavity 124 is substantially triangular, and, correspondingly, the body 10 has two slanting walls 1242, 1244 associated with the second cavity 124. The two slanting walls 1242, 1244 are joined/connected at a corner 1246.

The hook 14 is substantially C-shaped of and contains a hook body 142 and two arms 144. The hook body 142 extends directly from the top wall 1222 towards the corner 1246 and is located above the receiving portion 12. The two arms 144 are symmetrically formed on the hook body 142. The two arms 144, respectively, face towards the two sidewalls 1224 and are located above the receiving portion 12. There is a first space between a distal end of the hook body 142 and the corner 1246. There is a second space between each arm 144 and the corresponding sidewall 1224. A protrusion 1444 extends from a distal end of each arm 144 and towards the top wall 1222. Each protrusion 1444 is substantially a wedge in shape. Further, the receiving portion 12 and the hook 14 are, advantageously, integral/co-molded with one another, and additionally, both, usefully, are co-molded and thus integral with the body 10.

A block 16 is integrally (e.g., via co-molding) positioned in the receiving portion 12 and extends from one sidewall 1224 towards the other sidewall 1224. A top surface of the block 16 abuts against a bottom surface of the hook 14 but does not join therewith (i.e., the hook 14 and the block 16 effectively together create a snap latch).

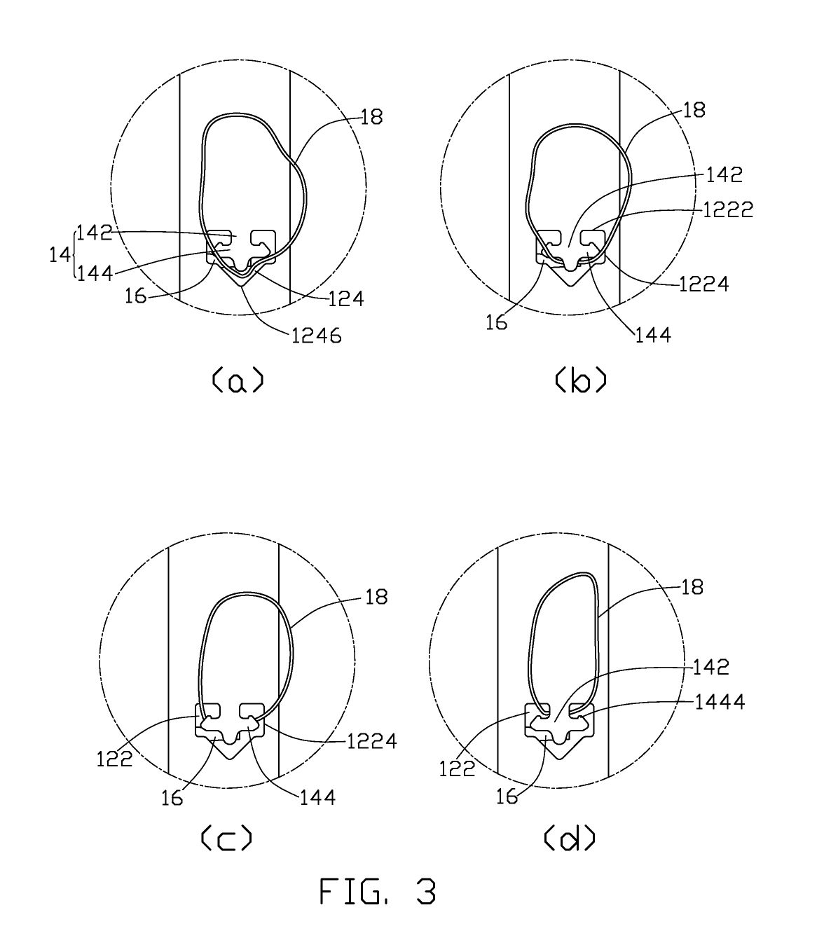

Also referring to FIGS. 3 (a)-(d), when assembling the line 18 to the housing mechanism 100, one portion of the line 18 travels through the first space between the hook body 142 and the corner 1246 and is located under the distal end of the hook body 142 and in the second cavity 124. The line 18 is then forced to travel towards the top wall 1222 between the hook 14 and the block 16 (i.e., snap-fit therebetween). The line 18 travels through the corresponding second spaces between the respective arms 144 and the corresponding sidewalls 1224. The line 18 is then completely mounted to the hook 14 and surrounds the hook body 142, as represented in FIG. 3 (d). The line 18 is not likely to slide away due to the two wedge-shaped protrusions 1444 and the snap engagement between the hook 14 and the block 16. Removal of the line 18 is a reverse process of the above-described assembling process.

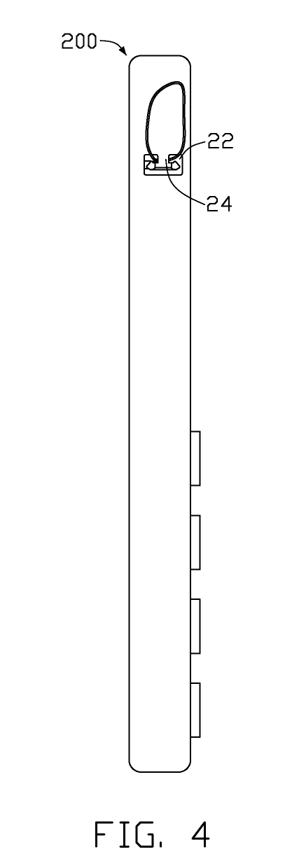

Also referring to FIG. 4, a housing mechanism 200 of a second present embodiment is similar to the housing mechanism 100 of the first embodiment, except that the housing mechanism 200 includes a substantially quadrate receiving portion 22 and a substantially inverse T-shaped hook 24.

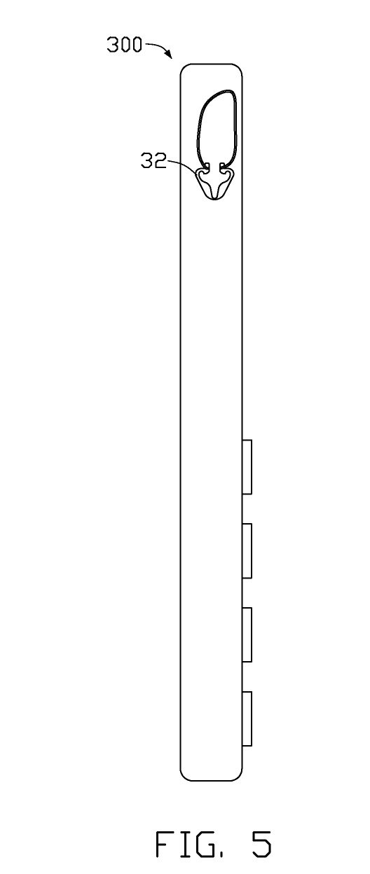

Also referring to FIG. 5, a housing mechanism 300 of a third present embodiment is similar to the housing mechanism 100 of the first embodiment, except that the housing mechanism 300 includes a substantially triangular receiving portion 32.

It should be understood that the receiving portion 12 may be defined in another portion of the body 10. The number of the arms 144 may, instead, be one. The receiving portion 12, the hook 14, and the block 16 are, advantageously, each formed of a durable material having a sufficient elastic modulus to permit an adequate snap-fit, as needed (i.e., reasonably easy to force the line 18 between the hook 14 and the block 16, but not prone to easy disengagement so as to securely hold the line 18). It is to be understood that the top of the block 16 could be rounded or beveled to promote ease of insertion of the line 18 between the hook 14 and the block 16. To promote retention, such beveling/rounding could be used only on the line-insertion side of the block 16 (i.e., much easier to insert than to remove).

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing mechanism for a portable electronic device, the housing mechanism comprising:
a body having a receiving portion defined therein, the body having a first wall and a second wall corresponding to the receiving portion; and
a hook having a hook body and at least one arm, the hook body extending from the first wall, towards the second wall, and above the receiving portion, the at least one arm extending from the hook body and extending above the receiving portion;
wherein there is a first space between the hook body and the second wall, and there is a second space between the at least one arm and the second wall.

2. The housing mechanism as claimed in claim 1, wherein a protrusion extends from a distal end of the at least one arm and towards the first wall.

3. The housing mechanism as claimed in claim 2, wherein the protrusion is substantially a wedge in shape.

4. The housing mechanism as claimed in claim 1, wherein the hook is substantially C-shaped.

5. The housing mechanism as claimed in claim 1, wherein the hook is substantially an inversed T-shape.

6. The housing mechanism as claimed in claim 1, wherein a block extends from the second wall and within the receiving portion, and the block abuts the hook.

7. The housing mechanism as claimed in claim 6, wherein a top end of the block has a rounded surface.

8. The housing mechanism as claimed in claim 6, wherein a top end of the block has a beveled surface.

9. The housing mechanism as claimed in claim 6, wherein the hook and the block are made of durable material having a sufficient elastic modulus to facilitate a snap-fit therebetween.
